(19) United States
(12) Patent Application Publication
(10) Pub. No.: US 2023/0229504 A1
(43) Pub. Date: Jul. 20, 2023

(54) HIGH DYNAMIC RANGE DIGITIZATION TECHNOLOGY FOR ANALOG COMPUTE-IN-MEMORY AND EDGE AI APPLICATIONS

(71) Applicant: Intel Corporation, Santa Clara, CA (US)

(72) Inventors: Renzhi Liu, Portland, OR (US); Hechen Wang, Portland, OR (US); Richard Dorrance, Hillsboro, OR (US); Deepak Dasalukunte, Beaverton, OR (US); Brent Carlton, Portland, OR (US)

(21) Appl. No.: 17/937,248

(22) Filed: Sep. 30, 2022

(51) Int. Cl. G06F 9/50; G06F 7/544; H03M 1/18

(52) U.S. Cl. CPC G06F 9/5027; G06F 7/5443; H03M 1/18

(57) ABSTRACT

Systems, apparatuses and methods may provide for compute-in-memory (CiM) accelerator technology that includes a multiply-accumulate (MAC) computation stage, an analog amplifier stage coupled to an output of the MAC computation stage, and an analog to digital conversion (ADC) stage coupled to an output of the analog amplifier stage, wherein a gain setting of the analog amplifier stage modifies a quantization granularity of the ADC stage.

### TECHNICAL FIELD

Embodiments generally relate to compute-in-memory (CiM) architectures. More particularly, embodiments relate to high dynamic range (HDR) digitation technology for analog CiM and edge artificial intelligence (AI) applications.

### BACKGROUND OF THE DISCLOSURE

Compute-in-Memory (CiM), one of the computation methods that is not based on the classical von Neumann architecture, becomes a promising candidate for current convolutional neural network (CNN) and deep neural network (DNN) applications. The development of CiM in pure digital systems, however, is more difficult to realize because conventional multiply-accumulate (MAC) operation units are typically too large to fit into high-density Manhattan style memory arrays. While advances may have been made in using analog computation in CiM-based architectures, there remains considerable room for improvement. For example, digitization accuracy on the analog value resulting from analog MAC (e.g., the output activation) may decrease significantly when the input activation vector is sparse and the expected MAC value is smaller than the analog to digital (ADC) quantization step.

### BRIEF DESCRIPTION OF THE DRAWINGS

The various advantages of the embodiments will become apparent to one skilled in the art by reading the following specification and appended claims, and by referencing the following drawings, in which:

FIG. 1 is a comparative illustration of an example of conventional multiply-accumulate (MAC) output value distributions and a MAC output value distribution according to an embodiment;

FIG. 2 is a comparative schematic diagram of an example of a conventional compute-in-memory (CiM) accelerator and an enhanced CiM accelerator according to an embodiment;

FIG. 3 is a schematic diagram of an example of an exponent quantizer stage that supports single-ended activation values according to an embodiment;

FIG. 4 is a schematic diagram of an example of an exponent quantizer stage that supports differential activation values according to an embodiment;

FIG. 5 is a flowchart of an example of a method of operating an accelerator according to an embodiment;

FIG. 6 is a flowchart of an example of a method of adjusting a gain setting of an analog amplifier stage according to an embodiment;

FIG. 7 is a block diagram of an example of a performance-enhanced computing system according to an embodiment; and

FIG. 8 is an illustration of an example of a semiconductor package apparatus according to an embodiment.

### DETAILED DESCRIPTION

Among existing compute-in-memory (CiM) solutions that primarily use digital computation schemes, only a small fraction of the entire memory array can be used for simultaneous computation with multi-bit data formats. This limitation is due to the digital computational circuit size for multi-bit data increasing quadratically with the number of bits, whereas the memory circuit size increases linearly. Accordingly, there is a significant size mismatch between the unit computational circuit and the unit memory cell for multi-bit implementations. As a result, only a small number of computational circuit units can be implemented for all-digital solutions, which creates significant bottlenecks in the overall throughput of in-memory computing.

To achieve efficient and high-throughput in-memory computing on multiply-accumulate (MAC) computation units, analog computation method based CiM works may have been developed in recent years. Challenges remain, however, with respect to computation resolution and accuracy. To address multi-bit weight and input activation representation as well as multi-bit analog MAC computation, recent developments have included a C-2C-ladder-based analog MAC unit for static random access memory (SRAM)-based CiM schemes as well as the construction of an analog in-memory computing macro with a standard SRAM macro.

There is still one aspect, however, of the challenge on high-precision analog computing that is not yet addressed—digitization accuracy on the output activation (e.g., analog value after performing analog MAC). Conventional analog-computation-based CiM schemes may use a conventional fixed-resolution ADC for MAC result digitization before processing the partial sum, applying the activation function, and feeding the outputs into the next layer (e.g., all occurring in the digital domain). In this case, the dynamic range of the data that can be digitized is the same as the ADC conversion resolution. Due to the classical tradeoff between ADC resolution and ADC conversion speed, the vast majority of the analog CiM solutions have been limited to no more than 8-bit ADC resolution, or 8-bit digitization dynamic range, while favoring a high conversion speed (e.g., which directly translates to higher MAC computation throughput and efficiency). Limiting the ADC resolution, however, substantially reduces the MAC computation accuracy even assuming that the ADC has ideal, error-free conversion. This reduced accuracy is due to the lack of ADC bits for conversion, which is essentially a digital truncation on those “missing” least significant bits (LSBs).

For example, in one conventional solution, a 64-dimensional analog MAC computation with 8-bit input activation and 8-bit weights is presented, and the output activation is quantized by an 8-bit ADC. In a counterpart full-digital implementation, such an arrangement would result in an ideal 8+8+6=22-bit after digital computation. Meanwhile, this specific analog implementation essentially has a truncation of fourteen bits on the LSB part by using an 8-bit ADC. This truncation can be problematic when the input activation vector is sparse and the expected MAC value is smaller than the ADC quantization step. To close this computation accuracy gap, one straightforward approach may be to have a higher resolution ADC such as, for example, twelve bits, which can reduce the number of truncated bits by four. Such an ADC, however, would result in much higher ADC power consumption at the same conversion speed (e.g., greater than 4-8× more power for a 12-bit ADC as compared to an 8-bit ADC), or significantly lower conversion speed if the ADC power is kept the same. In either case, the energy efficiency for analog computation degraded drastically.

To address this problem, technology described herein provides a high dynamic range (HDR) digitization scheme for analog CiM. The scheme increases the digitization dynamic range, or in other words, reduces the number of truncated bits during ADC conversion after analog MAC computation. Meanwhile, the raw ADC conversion resolution (e.g., number of raw ADC bits) is not increased.

More particularly, embodiments increase the digitization dynamic range on the analog MAC value in the context of analog in-memory computing. This increase digitization dynamic range is achieved by increasing the quantization granularity of an N-bit ADC to the level of an M+N bit ADC through up to 2^{M} times analog amplification for the ADC input, while not using an actual M+N bit ADC with significant overhead on power consumption and speed.

By conducting the pre-amplification on the ADC input (e.g., with 2^{M} times), a very small MAC output value now has an equivalent quantization granularity that only an M+N bit ADC can offer without preamplification. Meanwhile, for a very large MAC output value, amplification is bypassed to prevent the ADC quantization range from being exceeded. For very large inputs without preamplification, the quantization granularity is still the same as an N-bit ADC. Any MAC output value that has a preamplification gain in-between 1 and 2^{M}, would also have quantization granularity in-between what an N-bit and an M+N-bit ADC can offer.

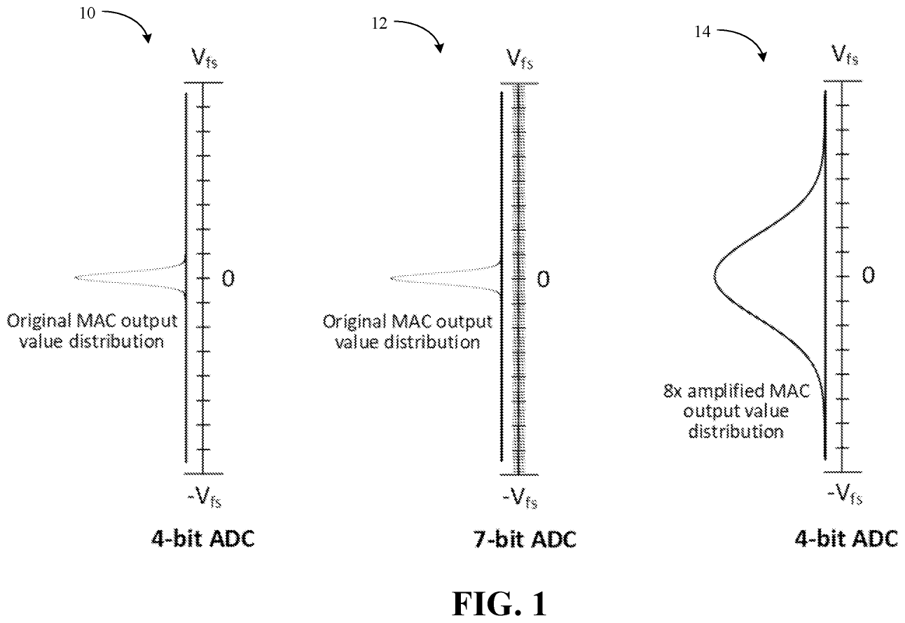

FIG. 1 illustrates the impact of ADC input pre-amplification for one example where relatively small MAC output values result from multiplication of sparse input activation and weights. A first conventional distribution 10 includes the original MAC output values with a very small distribution centered around zero while a 4-bit ADC with full scale range of [−Vfs, Vfs] is used for digitization. Almost all MAC outputs within the first conventional distribution 10 would be digitized as either 0 or ±1, with very poor quantization granularity. In a second conventional distribution 12, the ADC resolution is increased to 7-bit, which significantly improves the quantization granularity, but at the cost of much higher ADC complexity while still wasting most of the ADC quantization range. In an enhanced distribution 14, an 8× analog amplification is performed on the MAC output values while still using the 4-bit ADC. As a result, the enhanced distribution 14 is spread across the entire input range of the ADC, which makes the quantization results have the same quantization granularity as if a 7-bit ADC were used without MAC value amplification.

Embodiments also propose an exponent quantizer for the MAC output, from which result the proper preamplification gain can be set among 1, 2, 2², . . . , 2^{M} gain values. Accordingly, the gain value can be set to maximum while not exceeding ADC input range. In one example, the exponent quantizer is detects very small MAC output values while setting an appropriate gain for the amplifier.

Of particular note is that this scheme is not equivalent to directly having an M+N bit ADC, in which case the quantization step is uniformed. Therefore, this proposed scheme is not a general ADC resolution enhancement scheme, but rather a high dynamic range digitization scheme that is tailored to quantizing analog MAC computation outputs. Particularly, this scheme increases the quantization granularity of a fixed-resolution ADC (e.g., N-bit) when the MAC output value is very small.

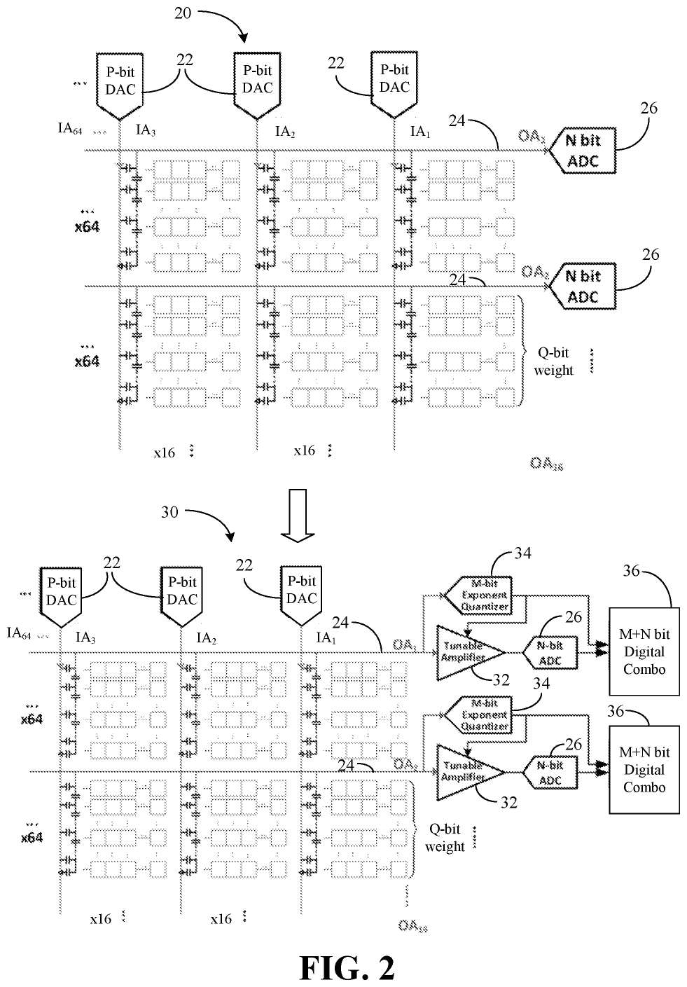

FIG. 2 demonstrates that one of the most significant challenges for analog in-memory computing is to quantize the result from analog MAC computation (e.g., the output activation/OA) with sufficient quantization granularity (e.g., a small enough quantization step) to not affect machine learning (ML) inference accuracy. More particularly, a conventional CiM accelerator 20 includes an OA quantization example in the context of a C-2C based analog in-memory computing array. Without losing generality, this C-2C based analog CiM array is used as an exemplary context for the purposes of discussion, while the technology described herein is not limited to this analog CiM implementation.

In the conventional CiM accelerator 20, an input activation (IA) is generated through P-bit DACs 22, and weight (W) has a Q-bit format (e.g., using a C-2C scheme for weighting). There are 64 products of IA×W summed together into one OA line 24 (e.g., analog MAC output), and the OA line 24 is quantized by an N-bit ADC 26. In a counterpart full-digital implementation, the OA line 24 may have a total of P+Q+6(=log₂64) bits of accuracy. Assuming P=Q=8 for a popular 8-bit integer (INT8) data format, the OA line 24 would have twenty-two bits of resolution in full-digital MAC computation. In comparison, due to ADC practicality and power/speed trade-off, the ADC resolution in an analog MAC implementation is mostly limited to around 8-bit (e.g., N≈8), as increasing the N value would incur exponentially higher ADC power consumption (e.g., truncating about fourteen LSB bits during the quantization in an analog solution). Although full 22-bit accuracy may not be necessary, as even the full-digital implementation will truncate for power saving, the analog solution faces the problem of too aggressive data truncation by design limitation rather than by choice.

To reduce the amount of data truncation by M bits, one way would be to provide an M+N bit ADC, making the digital data range to be [0, 2^{M+N}−1], or [−2^{M+N-1}, 2^{M+N-}−1] (e.g., with an offset, to better represent analog value with both positive and negative polarity). Such an approach, however, would be costly. Moreover, within such an M+N bit digital data range, the step size would uniformly be set as one. This approach may be useful when the input value is small because those values can be distinguished using a high-resolution ADC. When the input value is very large, however, such an approach is unnecessary (e.g., a low-resolution ADC is already sufficient for digitization).

Accordingly, an enhanced CiM accelerator 30 (e.g., in the same context of C-2C based analog CiM array) provides an HDR digitization scheme in which the quantization step is non-uniform. Specifically, the HDR digitization scheme has a small quantization step when the MAC output value is small, and a large quantization step when MAC output is large.

More particularly, two additional circuit blocks—a tunable amplifier 32 (e.g., analog amplifier stage) and an M-bit exponent quantizer 34 (e.g., exponent quantizer stage)—that precede the N-bit ADC 26 (e.g., ADC stage) are enhancements that enable an HDR digitization scheme with a variable quantization step for analog MAC values. In addition, there is a combination stage 36 (e.g., digital combination block) that follows the N-bit ADC 26 and M-bit exponent quantizer 34, to be discussed in greater detail.

Assuming that an analog MAC value “Vₐₙₐ” has a full-scale range of [−V_{fs}, V_{fs}], and the N-bit ADC 26 has the same full-scale data conversion range of [−V_{fs}, V_{fs}]. The proposed exponent quantizer 34 compares the absolute value of Vₐₙₐ, which is |Vₐₙₐ|, to a series of exponentially spaced quantization thresholds, which are

$$\frac{{V}_{fs}}{{2}^{M}} , \frac{{V}_{fs}}{{2}^{M - 1}} , … , \frac{{V}_{fs}}{{2}^{2}} , \frac{{V}_{fs}}{2} ,$$

and determines which two thresholds can bound the |Vₐₙₐ| value, for example,

$$\frac{{V}_{fs}}{{2}^{M - K + 1}} \leq \vert {V}_{ana} \vert < \frac{{V}_{fs}}{{2}^{M - K}} .$$

By doing so, Vₐₙₐ can at most be amplified by 2^{M-K}, without exceeding the full-scale conversion range of the following ADC 26.

The tunable amplifier 32 takes the result from the M-bit exponent quantizer 34 and conducts an analog value amplification of 2^{M-K} for Vₐₙₐ before sending the result into the N-bit ADC 26. With this variable amplification, a scaling down of the quantization step size of the N-bit ADC 26 is essentially achieved with respect to the original Vₐₙₐ value, and this scaling factor is based on how large or small the |Vₐₙₐ| value is. Thus, a dynamic quantization step is achieved for the MAC value Vₐₙₐ, which effectively increases the quantization dynamic range by up to M-bit when |Vₐₙₐ| is small.

Having the same full-scale range for the analog MAC value and ADC conversion range is a typical design point for analog CiM for maximizing the usage of ADC conversion range without analog MAC value overflow. With the presence of the tunable amplifier 32, however, in-between the analog MAC output and the input to the ADC 26, the two full scale ranges do not necessarily need to be the same. For example, if the analog MAC value has a full scale output range of [−V_{fs,ana}, V_{fs,ana}] and the ADC 26 has a full scale input range of [−V_{fs,adc}, V_{fs,adc}], another gain scaling factor of

$$\frac{{V}_{fs , adc}}{{V}_{fs , ana}}$$

could potentially be applied in addition to the previously mentioned gain settings on the tunable amplifier 32 (e.g., to close the gap between the two full-scale ranges). Due to the addition of the tunable amplifier 32, this operation almost comes at no cost, while in the conventional CiM accelerator 20, there is no easy way to implement such a solution other than forcing the analog MAC value and ADC input having the same full-scale range.

### Detailed HDR Digitization Steps

The proposed HDR digitization technology on the MAC result in analog CiM mainly involves four operations:

(1) Quantize the OA line 24 (e.g., analog MAC value), Vₐₙₐ, using an M-bit exponent quantizer. Assuming that the full-scale range of Vₐₙₐ is [−V_{fs}, V_{fs}], the M-bit exponent quantizer 34: (a) takes the absolute value of Vₐₙₐ as |Vₐₙₐ|; (b) finds K, such that

$$\frac{{V}_{fs}}{{2}^{M - K + 1}} \vert {V}_{ana} \vert < \frac{{V}_{fs}}{{2}^{M - K}} ( K = 1 , 2 , … , M ) , or \vert {V}_{ana} \vert < \frac{{V}_{fs}}{{2}^{M - K}} ( K = 0 ) ;$$

(c) since there only exists one and only one K value that can satisfy this condition, 2^{K} (K=0,1, . . . ,M) is then considered as the M-bit exponent quantizer result of Vₐₙₐ.

(2) Amplify the analog MAC value Vₐₙₐ by 2^{M-K} using the linear tunable amplifier 32 in the analog domain. As a result, the amplified value, Vₐₘₚ=2^{M-K}Vₐₙₐ, has a respective absolute value being bounded as follows:

$$\frac{{V}_{fs}}{2} \vert {V}_{amp} \vert < {V}_{fs} ( K = 1 , 2 , … , M ) , or \vert {V}_{amp} \vert < {V}_{fs} ( K = 0 ) .$$

(3) Digitize the amplified MAC value, Vₐₘₚ, using the N-bit ADC 26 that has a full-scale conversion range of [−V_{fs}, V_{fs}]. This linear ADC quantization process assumes that the quantization result of Vₐₘₚ can be expressed as Σᵢ₌₀^{N-1}(bᵢ·2ⁱ) (bᵢ=0,1). After adjusting for the mid-code offset to better represent a signed Vₐₘₚ value within the range of [−V_{fs}, V_{fs}], the quantization result becomes Σᵢ₌₀^{N-1}(bᵢ·2ⁱ)−2^{N-1}, where bᵢ=0 or 1. When K=M (e.g., when |V_{ana|} is large and there is no gain in operation (2)), the quantization step for both analog value Vₐₙₐ and Vₐₘₚ is the same, which is

$$\frac{2 \cdot {V}_{fs}}{{2}^{N}} ;$$

and when K=0 (e.g., when |Vₐₙₐ| is small and there is a maximum gain of 2^{M} in operation (2)), the quantization step for Vₐₘₚ is still

$$\frac{2 \cdot {V}_{fs}}{{2}^{N}} ,$$

meanwhile due to the 2^{M}× amplification relationship between Vₐₙₐ and Vₐₘₚ, now Vₐₙₐ has an effective quantization step of

$$\frac{2 \cdot {V}_{fs}}{{2}^{M \times N}} ,$$

which is 2^{M} times smaller than the former case. This small quantization step is the same as when an M+N bit ADC with a full-scale conversion range of [−V_{fs}, V_{fs}] is used.

(4) Use the combination stage 36 to combine the M-bit exponent quantizer result and the linear quantizer result from the N-bit ADC 26 in the digital domain. The result is the overall digital representation of analog value Vₐₙₐ as 2^{K}·(Σᵢ₌₀^{N-1}(bᵢ·2ⁱ)−2^{N-1}) (K=0, 1, . . . M; bᵢ0,1). When K=M, the quantized data range is [−2^{M+N-1}, 2^{M+N-1}−2^{M}], with a step size of 2^{M}; and when K=0, the quantized data range is [−2^{N-1}, 2^{N-1}−1], with a step size of one. In general, the step size of the proposed HDR digital representation is 2^{K}, where K is based on the exponent quantizer result.

As shown in operation (4), the overall digital data range is [−2^{M+N-1}, 2^{M+N-1}−2^{M}] which is almost the same as what an M+N bit ADC would provide (in which case, a data range of [−2^{M+N-1}, 2^{M+N-1}−1]). Accordingly, the dynamic range of digital representation of analog value Vₐₙₐ has been successfully increased from N-bit to M+N bit, by still using the N-bit ADC 26 while assisted by the M-bit exponent quantizer 34 and the analog tunable amplifier 32. The main difference is that, for an M+N bit ADC, one would have a uniformed step size of one within the data range, meanwhile the enhanced CiM accelerator 30 has a non-uniformed step size of 2^{K}, where K is based on the result of the exponent quantizer 34. The technology described herein can provide a very fine conversion step—the same as what an M+N bit ADC would provide—when the absolute of the MAC value, |Vₐₙₐ|, is very small, and a much coarser conversion step when |Vₐₙₐ| is large. Such a result is advantageous for resolving and quantizing a very small Vₐₙₐ when the vector is sparse (e.g., and the MAC output value is small). Meanwhile, for a very large Vₐₙₐ, the absolute accuracy of MAC output has much less impact on the overall neural network inference accuracy. Accordingly, a coarser quantization step is suitable for a large Vₐₙₐ.

Although examples use a digital value of Σᵢ₌₀^{N-1}(bᵢ·2ⁱ)−2^{N-1} from a binary (e.g., radix 2) ADC output, thus a digital data range of [−2^{N-1}, 2^{N-1}−1] for representing analog values in the range of [−V_{fs}, V_{fs}], there could be many other non-binary, but yet linear ADC conversion schemes, such as sub-2 radix ADC, for performing the linear ADC conversion. Also, there could be other data formats for the ADC output for representing analog values in the same full-scale range. Moreover, embodiments are not limited to only N-bit binary ADC conversion.

### Implementation Examples

Since the N-bit ADC 26 remains unchanged in the enhanced CiM accelerator 30 and the tunable amplifier 32 can use a wide range of existing tunable gain amplifier designs, examples focus on the implementation examples in the proposed M-bit exponent quantizer 34. Indeed, there exists many other exponent quantizer 34 implementations that still fall within HDR digitization technology described herein.

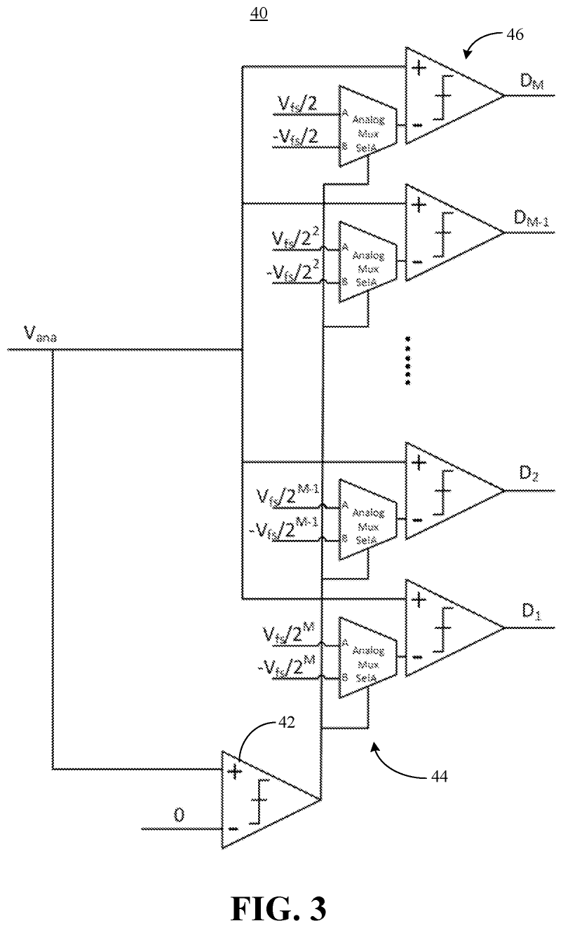

For example, FIG. 3 shows an M-bit exponent quantizer 40 that supports a single-ended analog output activation (OA) value of Vₐₙₐ in the range of [−V_{fs}, V_{fs}]. The exponent quantizer 40 may generally be substituted for the exponent quantizer 34 (FIG. 2), already discussed. In the illustrated example, the polarity of Vₐₙₐ is first taken by using a comparator 42 to compare Vₐₙₐ to zero. Then a set of multiplexers 44 and a set of comparators 46 is used to either compare Vₐₙₐ to

$$\frac{{V}_{fs}}{{2}^{M}} , \frac{{V}_{fs}}{{2}^{M - 1}} , … , \frac{{V}_{fs}}{{2}^{2}} , \frac{{V}_{fs}}{2}$$

if Vₐₙₙₐ is positive, or compare Vₐₙₐ to

$$- \frac{{V}_{fs}}{{2}^{M}} , - \frac{{V}_{fs}}{{2}^{M - 1}} , … , - \frac{{V}_{fs}}{{2}^{2}} , - \frac{{V}_{fs}}{2}$$

if Vₐₙₐ is negative. By doing so, potentially flipping the polarity of the variable Vₐₙₐ is avoided for taking the absolute value of Vₐₙₐ (e.g., which is costly in circuit implementation). Rather, the polarity of

$$\frac{{V}_{fs}}{{2}^{K}} ( K = 1 , 2 , … , M )$$

is flipped for comparison depending on the polarity of Vₐₙₐ (e.g., which is easier to implement as those thresholds are constant values). In the illustrated example, the M comparator results are denoted as D_{L} (L=1, 2, . . . , M).

Additionally, if Vₐnₐ is positive and

$$\frac{{V}_{fs}}{{2}^{M - K + 1}} \leq {V}_{ana} < \frac{{V}_{fs}}{{2}^{M - K}} , ( K = 1 , 2 , … , ) or {V}_{ana} < \frac{{V}_{fs}}{{2}^{M - K}} ( K = 0 ) .$$

then for the M comparator results, D_{L}=1 when L<K, and D_{L}=0 when L>K. Similarly, if Vₐₙₐ is negative and

$$- \frac{{V}_{fs}}{{2}^{M - K + 1}} \geq {V}_{ana} > - \frac{{V}_{fs}}{{2}^{M - K}} , ( K = 1 , 2 , … , M ) or {V}_{ana} > - \frac{{V}_{fs}}{{2}^{M - K}} ( K = 0 ) .$$

D_{L}=0 when L≤K, and D_{L}=1 when L>K. From the discussion above, both scenarios can be considered as having an M-bit exponent quantizer result of 2^{K}. During the actual exponent quantization process, this 2^{K} result can be decoded using Vₐₙₐ polarity and D_{L} (L=1, 2, . . . , M) results as there exists a one-to-one mapping between exponent quantization result and all feasible sets of comparator results.

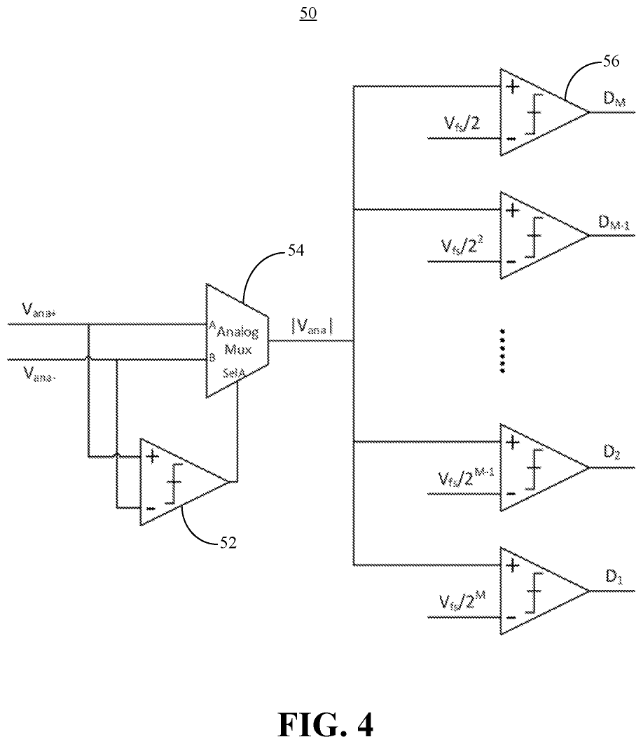

FIG. 4 shows an M-bit exponent quantizer 50 that supports differential OA values of Vₐₙₐ₊ and Vₐₙₐ₋, where Vₐₙₐ₊=−Vₐₙₐ₋ and both values have a full-scale range of [−V_{fs}, V_{fs}]. In this case, taking the absolute value is simpler, as a comparator 52 simply compares Vₐₙₐ₊ with Vₐₙₐ₋, and then a multiplexer 54 selects the larger value between the two values, which always has a positive value given the assumption of Vₐₙₐ₊=−Vₐₙₐ₋. The following comparison by a set of M comparators 56 is also simplified as the positive thresholds

$$\frac{{V}_{fs}}{{2}^{M}} , \frac{{V}_{fs}}{{2}^{M - 1}} , … , \frac{{V}_{fs}}{{2}^{2}} , \frac{{V}_{fs}}{2}$$

can always be used for the M comparators 56. The resulting decoding logic on D_{L} (L=1, 2, . . . , M) will be similar to the singled-ended case with Vₐₙₐ being positive.

Results for a simple example of a 4-layer machine language processor (MLP) trained to classify the Modified National Institute of Standards and Technology (MNIST) dataset (e.g., handwritten digits between zero and nine) using a MATLAB Deep Learning Toolbox have been advantageous. The original network achieves relatively high accuracy using single precision floating-point. After quantizing the network to 8-bits, however, the accuracy drops significantly. This lost accuracy could be recovered with retraining, but at the cost of weeks to months of extra development and computational time. Using the proposed HDR digitization technology, with a maximum amplification of sixteen (e.g., 4-bit exponent quantizer), the original accuracy was fully recovered.

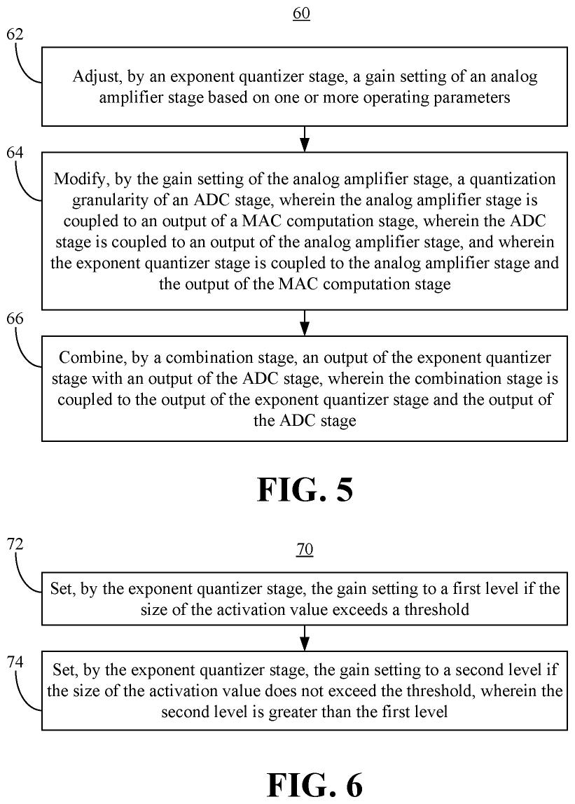

FIG. 5 shows a method 60 of operating an accelerator. The method 60 may generally be implemented in an accelerator such as, for example, the enhanced CiM accelerator 30 (FIG. 2), already discussed. More particularly, the method 60 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Illustrated processing block 62 adjusts, by an exponent quantizer stage, a gain setting of an analog amplifier stage based on one or more operating parameters. Alternatively, the gain setting may be fixed and/or changed at a frequency of less than once every cycle. Block 64 modifies, by the gain setting of the analog amplifier stage, a quantization granularity of an ADC stage, wherein the analog amplifier stage is coupled to an output of a MAC computation stage, wherein the ADC stage is coupled to an output of the analog amplifier stage, and wherein the exponent quantizer stage is coupled to the analog amplifier stage and the output of the MAC computation stage.

With regard to quantization granularity, quantization in digital signal processing is the process of mapping input values from a large set (often a continuous set) to output values in a (countable) smaller set, often with a finite number of elements. Rounding and truncation are typical examples of quantization processes. Quantization is involved to some degree in nearly all digital signal processing, as the process of representing a signal in digital form ordinarily involves rounding. Quantization also forms the core of essentially all lossy compression algorithms. The difference between an input value and its quantized value (such as round-off error) is referred to as quantization error. A device that performs quantization is called a quantizer and an analog-to-digital converter is an example of a quantizer. As already noted, the output of the MAC computation stage can include one or more of single-ended activation values or differential activation values.

In one example, the operating parameter(s) used to adjust the gain setting include a size of an activation value at the output of the MAC computation stage. In another example, the operating parameters include a type of neural network layer associated with the MAC computation stage. Illustrated block 66 combines, by a combination stage, an output of the exponent quantizer stage with an output of the ADC stage, wherein the combination stage is coupled to the output of the exponent quantizer stage and the output of the ADC stage. The method 60 therefore enhances performance at least to the extent that using the gain setting of the analog amplifier stage to modify the quantization granularity of the ADC stage improves output activation accuracy (e.g., when the input activation vector is sparse and the expected MAC value is smaller than the ADC quantization step) without increasing power consumption, reducing speed or increasing the cost of the ADC stage.

FIG. 6 shows a method 70 of adjusting a gain setting of an analog amplifier stage. The method 70 may generally be incorporated into block 62 (FIG. 5), already discussed. More particularly, the method 70 may be implemented in one or more modules as a set of logic instructions stored in a machine- or computer-readable storage medium RAM, ROM, PROM, firmware, flash memory, etc., in hardware, or any combination thereof

Illustrated processing block 72 sets, by an exponent quantizer stage, the gain setting to a first level if the size of the activation value at the output of the MAC computation stage exceeds a threshold. Block 74 sets, by the exponent quantizer stage the gain setting to a second level if the size of the activation value does not exceed the threshold, wherein the second level is greater than the first level. The method 70 therefore further enhances performance by dynamically increasing the equivalent quantization granularity of the ADC stage when the activation value is relatively small and preventing the activation value from exceeding the quantization range of the ADC stage when the activation value is relatively large.

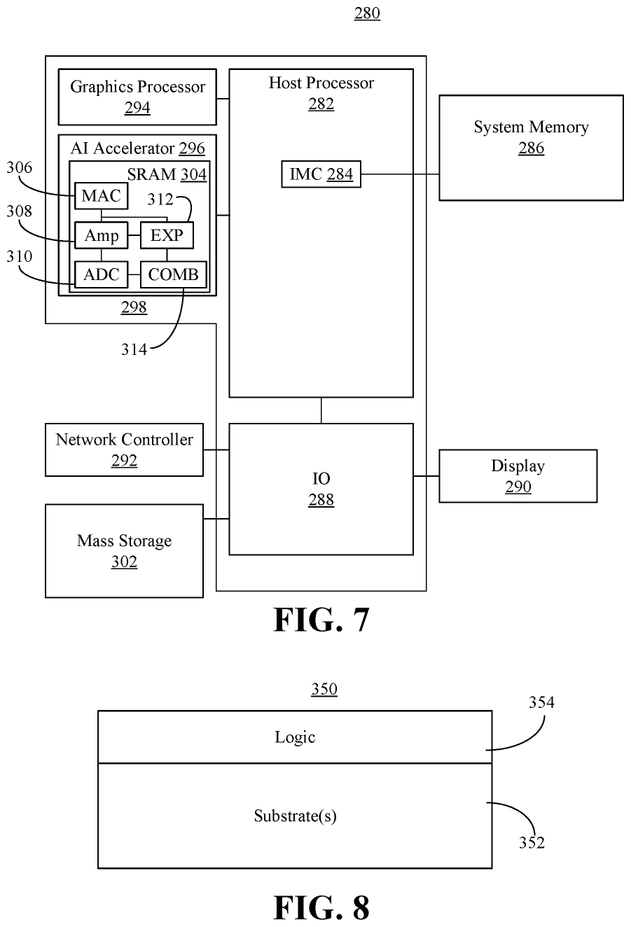

Turning now to FIG. 7, a performance-enhanced computing system 280 is shown. The system 280 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof

In the illustrated example, the system 280 includes a host processor 282 (e.g., central processing unit/CPU) having an integrated memory controller (IMC) 284 that is coupled to a system memory 286 (e.g., dual inline memory module/DIMM). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an AI accelerator 296 (e.g., CiM accelerator) into a system on chip (SoC) 298.

In an embodiment, the AI accelerator 296 performs one or more aspects of the method 60 (FIG. 5) and/or the method 70 (FIG. 6), already discussed. Thus, AI accelerator 296 includes a memory array 304 (e.g., SRAM), a MAC computation stage 306, an analog amplifier stage 308 coupled to an output of the MAC computation stage 306, and an ADC stage 310 coupled to an output of the analog amplifier stage 308, wherein a gain setting of the analog amplifier stage 308 is to modify a quantization granularity of the ADC stage 310. The AI accelerator 296 may also include an exponent quantizer stage 312 coupled to the analog amplifier stage 308 and the output of the MAC computation state 306, wherein the exponent quantizer stage 312 is to adjust the gain setting based on one or more operating parameters (e.g., the size of the activation value, the type of neural network layer, etc.).

The illustrated AI accelerator 296 also includes a combination stage 314 coupled to an output of the exponent quantizer stage 312 and an output of the ADC stage 310, wherein the combination stage 314 is to combine the output of the exponent quantizer stage 312 and the output of the ADC stage 310. The enhanced CiM accelerator 30 (FIG. 2), already discussed, may be readily substituted for the AI accelerator 296. The computing system 280 is therefore considered performance-enhanced at least to the extent that using the gain setting of the analog amplifier stage 308 to modify the quantization granularity of the ADC stage 310 improves output activation accuracy (e.g., when the input activation vector is sparse and the expected MAC value is smaller than the ADC quantization step) without increasing power consumption, reducing speed or increasing the cost of the ADC stage.

FIG. 8 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. In an embodiment, the logic 354 implements one or more aspects of the method 60 (FIG. 5) and/or the method 70 (FIG. 6), already discussed. The logic 354 may also include the enhanced CiM accelerator 30 (FIG. 2) and/or the AI accelerator 296 (FIG. 7), already discussed.

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

### Additional Notes and Examples

Example 1 includes a performance-enhanced computing system comprising a memory array and a compute-in-memory (CiM) accelerator coupled to the memory array, the CiM accelerator including a multiply-accumulate (MAC) computation stage, an analog amplifier stage coupled to an output of the MAC computation stage, and an analog to digital conversion (ADC) stage coupled to an output of the analog amplifier stage, wherein a gain setting of the analog amplifier stage is to modify a quantization granularity of the ADC stage.

Example 2 includes the computing system of Example 1, wherein the CiM accelerator further includes an exponent quantizer stage coupled to the analog amplifier stage and the output of the MAC computation stage, wherein the exponent quantizer stage is to adjust the gain setting based on one or more operating parameters.

Example 3 includes the computing system of Example 2, wherein the one or more operating parameters include a size of an activation value at the output of the MAC computation stage.

Example 4 includes the computing system of Example 3, wherein the exponent quantizer stage is to set the gain setting to a first level if the size of the activation value exceeds a threshold, and set the gain setting to a second level if the size of the activation value does not exceed the threshold, wherein the second level is greater than the first level.

Example 5 includes the computing system of Example 2, wherein the one or more operating parameters include a type of neural network layer associated with the MAC computation stage.

Example 6 includes the computing system of Example 2, wherein the CiM accelerator further includes a combination stage coupled to an output of the exponent quantizer stage and an output of the ADC stage, and wherein the combination stage is to combine the output of the exponent quantizer stage and the output of the ADC stage.

Example 7 includes the computing system of Example 1, wherein the gain setting is fixed.

Example 8 includes the computing system of any one of Examples 1 to 7, wherein the output of the MAC computation stage is to include one or more of single-ended activation values or differential activation values.

Example 9 includes a compute-in-memory (CiM) accelerator comprising a multiply-accumulate (MAC) computation stage, an analog amplifier stage coupled to an output of the MAC computation stage, and an analog to digital conversion (ADC) stage coupled to an output of the analog amplifier stage, wherein a gain setting of the analog amplifier stage is to modify a quantization granularity of the ADC stage.

Example 10 includes the CiM accelerator of Example 9, further including an exponent quantizer stage coupled to the analog amplifier stage and the output of the MAC computation stage, wherein the exponent quantizer stage is to adjust the gain setting based on one or more operating parameters.

Example 11 includes the CiM accelerator of Example 10, wherein the one or more operating parameters include a size of an activation value at the output of the MAC computation stage.

Example 12 includes the CiM accelerator of Example 11, wherein the exponent quantizer stage is to set the gain setting to a first level if the size of the activation value exceeds a threshold, and set the gain setting to a second level if the size of the activation value does not exceed the threshold, wherein the second level is greater than the first level.

Example 13 includes the CiM accelerator of Example 10, wherein the one or more operating parameters include a type of neural network layer associated with the MAC computation stage.

Example 14 includes the CiM accelerator of Example 10, further including a combination stage coupled to an output of the exponent quantizer stage and an output of the ADC stage, wherein the combination stage is to combine the output of the exponent quantizer stage and the output of the ADC stage.

Example 15 includes the CiM accelerator of Example 9, wherein the gain setting is fixed.

Example 16 includes the CiM accelerator of any one of Examples 9 to 15, wherein the output of the MAC computation stage is to include single-ended activation values.

Example 17 includes the CiM accelerator of any one of Examples 9 to 15, wherein the output of the MAC computation stage is to include differential activation values.

Example 18 includes a method of operating a compute-in-memory (CiM) accelerator, the method comprising modifying, by a gain setting of an analog amplifier stage, a quantization granularity of an analog to digital conversion (ADC) stage, wherein the analog amplifier stage is coupled to an output of a multiply-accumulate (MAC) computation stage, and wherein the ADC stage is coupled to an output of the analog amplifier stage.

Example 19 includes the method of Example 18, further including adjusting, by an exponent quantizer stage, the gain setting based on one or more operating parameters, wherein the exponent quantizer stage is coupled to the analog amplifier stage and the output of the MAC computation stage.

Example 20 includes the method of Example 19, wherein the one or more operating parameters include a size of an activation value at the output of the MAC computation stage.

Example 21 includes the method of Example 20, further including setting, by the exponent quantizer stage, the gain setting to a first level if the size of the activation value exceeds a threshold, and setting, by the exponent quantizer stage, the gain setting to a second level if the size of the activation value does not exceed the threshold, wherein the second level is greater than the first level.

Example 22 includes the method of Example 19, wherein the one or more operating parameters include a type of neural network layer associated with the MAC computation stage.

Example 23 includes the method of Example 19, further including combining, by a combination stage, an output of the exponent quantizer stage with an output of the ADC stage, wherein the combination stage is coupled to the output of the exponent quantizer stage and the output of the ADC stage.

Example 24 includes the method of Example 18, wherein the gain setting is fixed.

Example 25 includes the method of any one of Examples 18 to 24, wherein the output of the MAC computation stage includes one or more of single-ended activation values or differential activation values.

Example 26 includes an apparatus comprising means for performing the method of any one of Examples 18 to 25.

Technology described herein therefore provides superior performance advantages to analog in-memory computing solutions, which is especially beneficial for edge AI platforms with respect to achieving high throughput and high efficiency. The technology addresses one of the most significant limitations of analog CiM—a lack of output activation accuracy.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a memory array; and
an accelerator coupled to the memory array, the accelerator including:
a multiply-accumulate (MAC) computation stage,
an analog amplifier stage coupled to an output of the MAC computation stage, and
an analog to digital conversion (ADC) stage coupled to an output of the analog amplifier stage, wherein a gain setting of the analog amplifier stage is to modify a quantization granularity of the ADC stage.

2. The computing system of claim 1, wherein the accelerator further includes an exponent quantizer stage coupled to the analog amplifier stage and the output of the MAC computation stage, wherein the exponent quantizer stage is to adjust the gain setting based on one or more operating parameters.

3. The computing system of claim 2, wherein the one or more operating parameters include a size of an activation value at the output of the MAC computation stage.

4. The computing system of claim 3, wherein the exponent quantizer stage is to:
set the gain setting to a first level if the size of the activation value exceeds a threshold; and
set the gain setting to a second level if the size of the activation value does not exceed the threshold, wherein the second level is greater than the first level.

5. The computing system of claim 2, wherein the one or more operating parameters include a type of neural network layer associated with the MAC computation stage.

6. The computing system of claim 2, wherein the accelerator further includes a combination stage coupled to an output of the exponent quantizer stage and an output of the ADC stage, and wherein the combination stage is to combine the output of the exponent quantizer stage and the output of the ADC stage.

7. The computing system of claim 1, wherein the gain setting is fixed.

8. The computing system of claim 1, wherein the output of the MAC computation stage is to include one or more of single-ended activation values or differential activation values.

9. An accelerator comprising:
a multiply-accumulate (MAC) computation stage;
an analog amplifier stage coupled to an output of the MAC computation stage; and
an analog to digital conversion (ADC) stage coupled to an output of the analog amplifier stage, wherein a gain setting of the analog amplifier stage is to modify a quantization granularity of the ADC stage.

10. The accelerator of claim 9, further including an exponent quantizer stage coupled to the analog amplifier stage and the output of the MAC computation stage, wherein the exponent quantizer stage is to adjust the gain setting based on one or more operating parameters.

11. The accelerator of claim 10, wherein the one or more operating parameters include a size of an activation value at the output of the MAC computation stage.

12. The accelerator of claim 11, wherein the exponent quantizer stage is to:
set the gain setting to a first level if the size of the activation value exceeds a threshold; and
set the gain setting to a second level if the size of the activation value does not exceed the threshold, wherein the second level is greater than the first level.

13. The accelerator of claim 10, wherein the one or more operating parameters include a type of neural network layer associated with the MAC computation stage.

14. The accelerator of claim 10, further including a combination stage coupled to an output of the exponent quantizer stage and an output of the ADC stage, wherein the combination stage is to combine the output of the exponent quantizer stage and the output of the ADC stage.

15. The accelerator of claim 9, wherein the gain setting is fixed.

16. The accelerator of claim 9, wherein the output of the MAC computation stage is to include single-ended activation values.

17. The accelerator of claim 9, wherein the output of the MAC computation stage is to include differential activation values.

18. A method comprising:
modifying, by a gain setting of an analog amplifier stage, a quantization granularity of an analog to digital conversion (ADC) stage, wherein the analog amplifier stage is coupled to an output of a multiply-accumulate (MAC) computation stage, and wherein the ADC stage is coupled to an output of the analog amplifier stage.

19. The method of claim 18, further including adjusting, by an exponent quantizer stage, the gain setting based on one or more operating parameters, wherein the exponent quantizer stage is coupled to the analog amplifier stage and the output of the MAC computation stage.

20. The method of claim 19, wherein the one or more operating parameters include a size of an activation value at the output of the MAC computation stage.

21. The method of claim 20, further including:
setting, by the exponent quantizer stage, the gain setting to a first level if the size of the activation value exceeds a threshold; and
setting, by the exponent quantizer stage, the gain setting to a second level if the size of the activation value does not exceed the threshold, wherein the second level is greater than the first level.

22. The method of claim 19, wherein the one or more operating parameters include a type of neural network layer associated with the MAC computation stage.

23. The method of claim 19, further including combining, by a combination stage, an output of the exponent quantizer stage with an output of the ADC stage, wherein the combination stage is coupled to the output of the exponent quantizer stage and the output of the ADC stage.

24. The method of claim 18, wherein the gain setting is fixed.

25. The method of claim 18, wherein the output of the MAC computation stage includes one or more of single-ended activation values or differential activation values.
